(19) United States
(12) Patent Application Publication
(10) Pub. No.: US 2012/0247562 A1
(43) Pub. Date: Oct. 4, 2012

(54) DYE-SENSITIZED SOLAR CELL AND METHOD OF MANUFACTURING THE SAME

(75) Inventors: Kazukuni NISHIMURA, Tokyo (JP); Kazuya ISOBE, Tokyo (JP); Teruo SASAKI, Tokyo (JP)

(73) Assignee: KONICA MINOLTA BUSINESS TECHNOLOGIES, INC., Tokyo (JP)

(21) Appl. No.: 13/426,016

(22) Filed: Mar. 21, 2012

(30) Foreign Application Priority Data
Mar. 31, 2011 (JP) 2011-078776

(51) Int. Cl. H01L 51/46

(52) U.S. Cl. 136/263

(57) ABSTRACT

Provided are a dye-sensitized solar cell with which desired photoelectric conversion efficiency is obtained when short-circuiting between a photoelectric conversion layer and a charge transport layer is suppressed, and also a manufacturing method thereof. Disclosed is a dye-sensitized solar cell comprising a photoelectric conversion element comprising a substrate and layered thereon, a first electrode layer, a photoelectric conversion layer in which a sensitizing dye is carried onto a semiconductor material, a charge transport layer and a second electrode layer in this order, wherein the photoelectric conversion layer comprises a compound represented by the following Formula (1): Formula (1) (R-A)ₙ-M, where R represents a monovalent organic group having a straight-chain structure having no substituent but at least 6 atoms in chain length at a terminal, A represents an oxo acid group, M represents a metal atom, and n is an integer of 2-5.

This application claims priority from Japanese Patent Application No. 2011-078776 filed on Mar. 31, 2011, which is incorporated hereinto by reference.

### TECHNICAL FIELD

The present invention relates to a dye-sensitized solar cell and a method of manufacturing the dye-sensitized solar cell.

### BACKGROUND

In recent years, application of infinite solar light producing no harmful substances has been actively studied as an energy source. Those presently available in practical use as a clean energy source in application of solar light are solar cells for domestic use, and specific examples thereof include single crystalline silicon, polycrystalline silicon, amorphous silicon, and cadmium telluride and indium copper selenide.

However, as drawbacks of these inorganic type solar cells, in the case of the silicon type, not only extremely high purity silicon is required, but also the complicated purification process includes a number of steps at high production coat.

Further, many solar cells each in which an organic material is used have also been proposed. Examples of the organic solar cell include a Schottky type photoelectric conversion element in which a p-type organic semiconductor and metal having a small work function are jointed, and a heterojunction type photoelectric conversion element in which a p-type organic semiconductor and an n-type inorganic semiconductor, or a p-type organic semiconductor and an electron acceptable organic compound are jointed. Examples of organic semiconductors used for these include synthesized dyes or pigments such as chlorophyll, perylene and so forth, conductive polymeric materials such as polyacetylene and so forth, and their composite material. A solar cell is made from those thin-layered by a vacuum evaporation method, a casting method, a dipping method or the like. The battery material used for an organic semiconductor has advantages of low cost and easy production for large area, but there is a problem such as a low conversion efficiency of 1% or less together with insufficient durability.

With respect to such a problem, a dye-sensitized solar cell is proposed as a solar cell exhibiting excellent conversion efficiency. Specifically, the dye-sensitized solar cell is constituted and formed so as to face a semiconductor electrode in which a photoelectric conversion layer formed via adsorption of a sensitizing dye to a semiconductor porous material such as titanium oxide or the like is layered on a conductive layer in a conductive support obtained by layering the conductive layer on a substrate, and the second electrode layer electrically connected to the conductive layer via a charge transport layer.

However, there was a problem such that a photoelectric conversion layer in this dye-sensitized solar cell did not exhibit desired photoelectric conversion efficiency, since there was a portion where electrons transferred in the reverse direction were generated by short-circuiting an electron transport layer. This problem was saliently produced, in particular, in cases where the charge transport layer was formed of a solid material.

As to short-circuiting between the photoelectric conversion layer and the charge transport layer, it would appear that since there is, in no small part, a non-adsorption site where no sensitizing dye is adsorbed onto the surface of a semiconductor porous material, electrons transferred in the reverse direction are to be generated when such a non-adsorption site is brought into contact with a charge transfer layer. In addition, for the purpose of reducing such a non-adsorption site, a technique in which an organic acid molecule exhibiting no electron-releasing property but having a hydrophobic group in addition to a sensitizing dye is adsorbed is reported in Patent Document 1.

However, even though utilizing such a technique, it is still hard to say in the current situation that short-circuiting between the photoelectric conversion layer and the charge transport layer can be efficiently suppressed.

### PATENT DOCUMENT

Patent Document 1: Published Japanese translation of PCT international Publication No. 2006-525632.

### SUMMARY

The present invention was made on the basis of the above-described situation, and it is an object of the present invention to provide a dye-sensitized solar cell with which desired photoelectric conversion efficiency is obtained when short-circuiting between a photoelectric conversion layer and a charge transport layer is suppressed. Further, it is another object of the present invention to provide a method of manufacturing a dye-sensitized solar cell, by which the dye-sensitized solar cell exhibiting high photoelectric conversion efficiency is obtained when short-circuiting between the photoelectric conversion layer and the charge transport layer is suppressed.

### BRIEF DESCRIPTION OF THE DRAWINGS

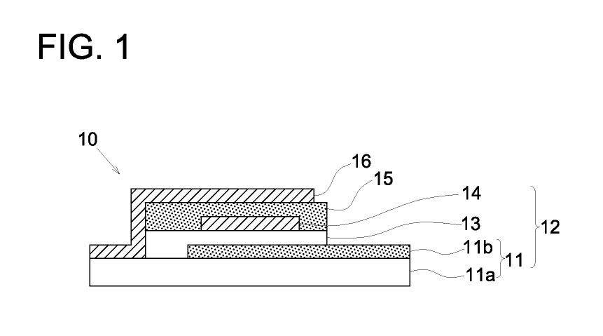

Embodiments will now be described, by way of example only, with reference to the accompanying drawing which is meant to be exemplary, not limiting, and wherein like elements numbered alike in the figure, in which: FIG. 1 is a cross-sectional diagram showing an example of configuration of a dye-sensitized solar cell of the present invention.

### DESCRIPTION OF THE PREFERRED EMBODIMENTS

A dye-sensitized solar cell of the present invention comprises a photoelectric conversion element comprising a substrate and layered thereon, a first electrode layer, a photoelectric conversion layer in which a sensitizing dye is carried onto a semiconductor material, a charge transport layer and a second electrode layer in this order, wherein the photoelectric conversion layer comprises a compound represented by the following Formula (1): Formula (1) (R-A)ₙ-M, where R represents a monovalent organic group having a straight-chain structure having no substituent but at least 6 atoms in chain length at a terminal, A represents an oxo acid group, M represents a metal atom, and n is an integer of 2-5.

As to the dye-sensitized solar cell of the present invention, it is preferable that n in Formula (1) is 2, and M represents an element in Group 2 or Group 12.

Further, as to the dye-sensitized solar cell of the present invention, it is preferable that R in Formula (1) represents a straight-chain alkyl group having 6-30 carbon atoms.

Further, as to the dye-sensitized solar cell of the present invention, it is preferable that A in Formula (1) represents a carboxylic acid group.

Further, as to the dye-sensitized solar cell of the present invention, the charge transport layer is designed to be in the form of a solid.

Further, as to the dye-sensitized solar cell of the present invention, the semiconductor material preferably comprises titanium oxide.

It is a feature in a method of preparing the dye-sensitized solar cell of the present invention that the steps of forming a semiconductor layer comprising the semiconductor material on the first electrode layer provided on the substrate, adsorbing the sensitizing dye onto a surface of the semiconductor layer, and subsequently adsorbing the compound represented by the foregoing Formula (1) onto the surface of the semiconductor layer are conducted to prepare the photoelectric conversion layer.

While the preferred embodiments of the present invention have been described using specific terms, such description is for illustrative purposes only, and it is to be understood that changes and variations may be made without departing from the spirit or scope of the appended claims.

### DETAILED DESCRIPTION OF THE INVENTION

Next, the present invention will be specifically explained.

### [Photoelectric Conversion Element]

Photoelectric conversion element 10 constituting a dye-sensitized solar cell of the present invention is one in which semiconductor element 12 and second electrode layer 16 are placed opposed via charge transport layer 15, wherein the semiconductor element 12 possesses conductive support 11 having transparent substitute 11a and provided thereon, first electrode layer 11b; and further possesses transparent insulating layer 13 provided on the first electrode layer 11b, and photoelectric conversion layer 14 placed on the first electrode layer 11b via the transparent insulating layer 13, and the photoelectric conversion layer 14 contains a compound represented by Formula (1) described above (hereinafter, referred to also as “co-adsorption compound”). The dye-sensitized solar cell of the present invention possesses at least one photoelectric conversion element 10 described above, and is composed of a structure so as to suitably conduct photoelectric conversion thereof when designing suitable for solar light is made to design a circuit suitable for solar light and the solar light is used as a light source.

In photoelectric conversion element 10, first electrode layer 11b and second electrode layer 16 as a second electrode layer are electrically connected via wire connection, and photocurrent can be taken out by making solar light or electromagnetic waves equivalent to the solar light to be incident from the transparent substrate 11a side. Specifically, when solar light entering after transmitting conductive support 11 is absorbed by a sensitizing dye in the ground state, which has been carried onto the surface of a semiconductor material constituting photoelectric conversion layer 14, this sensitizing dye is excited, whereby electrons are generated. These electrons are injected into the semiconductor material, and electrons injected into this semiconductor material are diffused in photoelectric conversion layer 14 and introduced into second electrode layer 16 via first electrode layer 11b and wire connection, whereby a constituting material contained in charge transport layer 15 is to be reduced in second electrode layer 16. On the other hand, a sensitizing dye having become an oxidant via loss of electrons is reduced and returns to the ground state when electrons are supplied from charge electron layer 15. At the same time, a constituting material contained in charge transfer layer 15 is oxidized and returns again to the state capable of being reduced by electrons supplied from second electrode layer 16. From a series of those described above, electromotive force is generated between second electrode layer 16 and first electrode layer 11b provided in conductive support 11, which is electrically connected with photoelectric connection layer 14.

### [Conductive Support]

Photoelectric conversion element 10 in this example is constituted as one making light to be incident from the conductive support 11 side, and conductive support 11 in this example is one in which first electrode layer 11b composed of a transparent conductive layer or the like is formed on transparent substrate 11a, wherein this conductive support 11 is substantially transparent. Herein, the term “substantially transparent” means that transmittance is at least 10%, preferably at least 50%, and more preferably at least 80%. A glass plate, a plastic film and so forth are usable as transparent substrate 11a constituting conductive support 11, and examples of material constituting first electrode layer 11b provided in conductive support 11 include conductive metal oxide such as indium-tin composite oxide (ITO), fluorine-doped tin oxide (FTO) or the like, and those made of carbon. Transparent substrate 11a constituting photoelectric conversion element 10 of the present invention is preferably one exhibiting flexibility. Further, when being constituted as one making light to be incident from the second electrode layer 16 side, second electrode layer 16 may be one which is substantially transparent, similarly to the foregoing first electrode layer 11b.

Conductive support 11 preferably has a surface resistance of 50 Ω/□ or less and more preferably has a surface resistance of 10 Ω/□ or less.

### [Insulating Layer]

Insulating layer 13 is a layer serving as a short-circuit prevention layer, and inserted between photoelectric conversion layer 14 and first electrode layer 11b provided in conductive support 11, if desired. The material constituting layer 13 may be those exhibiting not only insulation but also transparency, if desired.

Insulating layer 13 preferably has a thickness of 50-500 nm in view of reverse-current prevention and transparency.

### [Photoelectric Conversion Layer]

Photoelectric conversion layer 14 is one exhibiting electron transport ability, in which a sensitizing dye is carried onto a semiconductor material, and a co-adsorption compound is contained. Specifically, photoelectric conversion layer 14 is preferably one in which a sensitizing dye and a co-adsorption compound are adsorbed onto a semiconductor material together.

### [Semiconductor Material]

A semiconductor material constituting photoelectric conversion layer 14 is one producing electron transport action, and examples of the semiconductor made of such a semiconductor material include a compound containing an element in Groups 3-5 and Groups 13-15 of the periodic table (referred to also as the element periodic table), a metal chalcogenide such as oxide, sulfide, selenide or the like, a metal nitride, and so forth. Examples of metal chalcogenide include an oxide of titanium, tin, zinc, iron, tungsten, zirconium, hafnium, strontium, indium, cerium, yttrium, lanthanum, vanadium, niobium or tantalum; a sulfide of cadmium, zinc, lead, silver, antimony or bismuth; a selenide of cadmium or lead; a telluride of cadmium; and so forth. Usable examples thereof also include a phosphide of zinc, gallium, indium, cadmium or the like; a selenide of gallium-arsenic or copper-indium; a sulfide of copper-indium; a nitride of titanium; and so forth. Specific examples include TiO₂, SnO₂, Fe₂O₃, WO₃, ZnO, Nb₂O₅, CdS, ZnS, PbS, Bi₂S₃, CdSe, CdTe, GaP, Inp, GaAs, CuInS₂, CuInSe₂, Ti₃N₄ and so forth. Of these, TiO₂, ZnO, SnO₂, Fe₂O₃, WO₃, Nb₂O₅, CdS and PbS are preferably usable; TiO₂ and Nb₂O₅ arc more preferably usable; and TiO₂ is most preferably usable. These semiconductors are also usable in mixture in combination with at least two kinds thereof. For example, 20% by weight of titanium nitride (Ti₃N₄) may be mixed in titanium oxide semiconductor to be used. Further, for example, the zinc oxide/tin oxide composite described in J. Chem. Soc., Chem. Commun., 15 (1999) is also usable. When a component other than metal oxide or metal sulfide is added as a semiconductor, a content of such the addition component is preferably 30% by weight with respect to the metal oxide or metal sulfide semiconductor.

Photoelectric conversion layer 14 preferably has a thickness of 1-20 μm.

### [Sensitizing Dye]

The sensitizing dye carried onto a semiconductor material in photoelectric conversion layer 14 is not specifically limited as long as it exhibits sensitization action, and various commonly known sensitizing dyes are usable, but those each having a carboxyl group are preferably used in view of efficient injection of charge into the semiconductor material. Specific examples of the sensitizing dyes are represented by D-1 to D-43, but are not limited thereto. The following sensitizing dyes are usable singly or in mixture in combination with at least two kinds thereof.

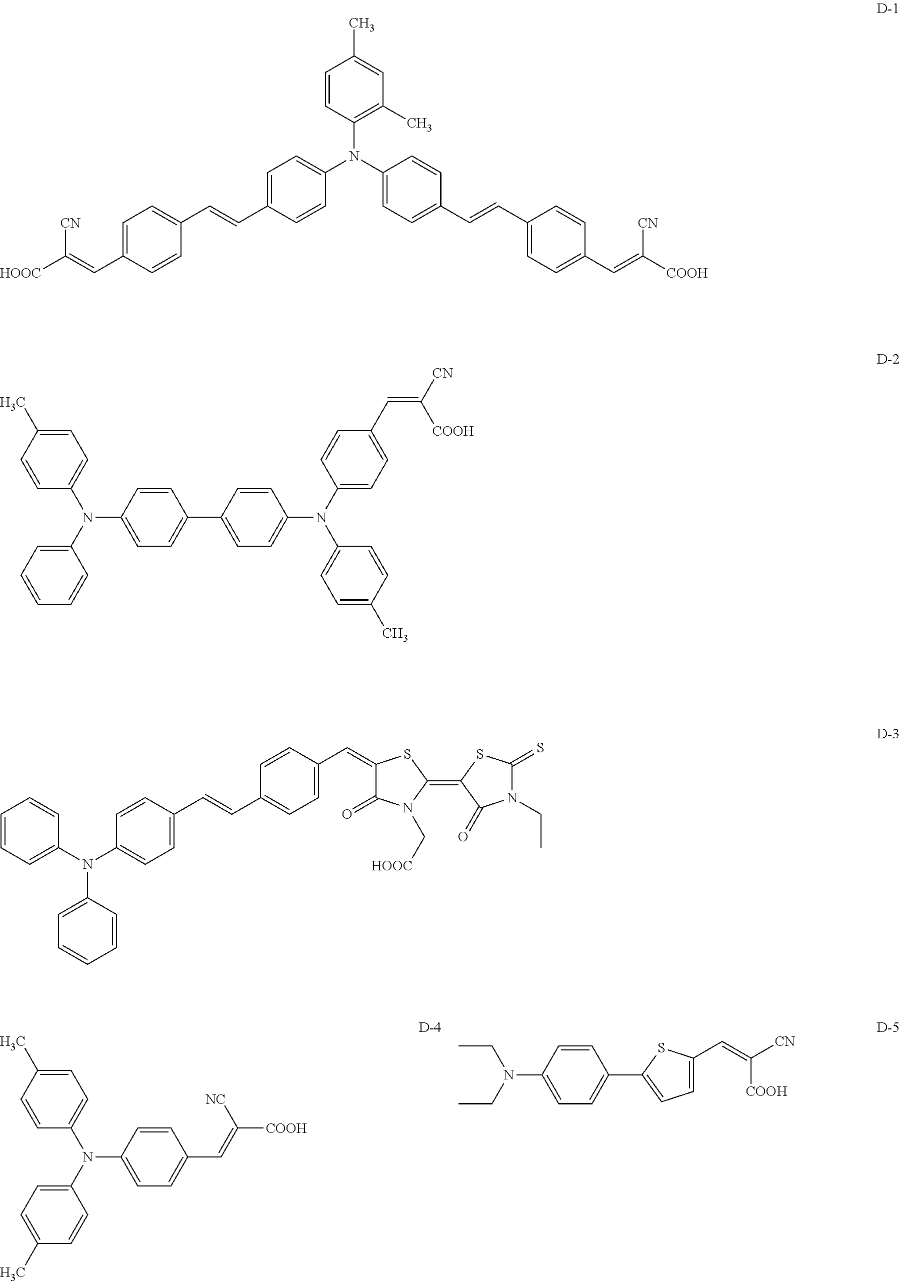

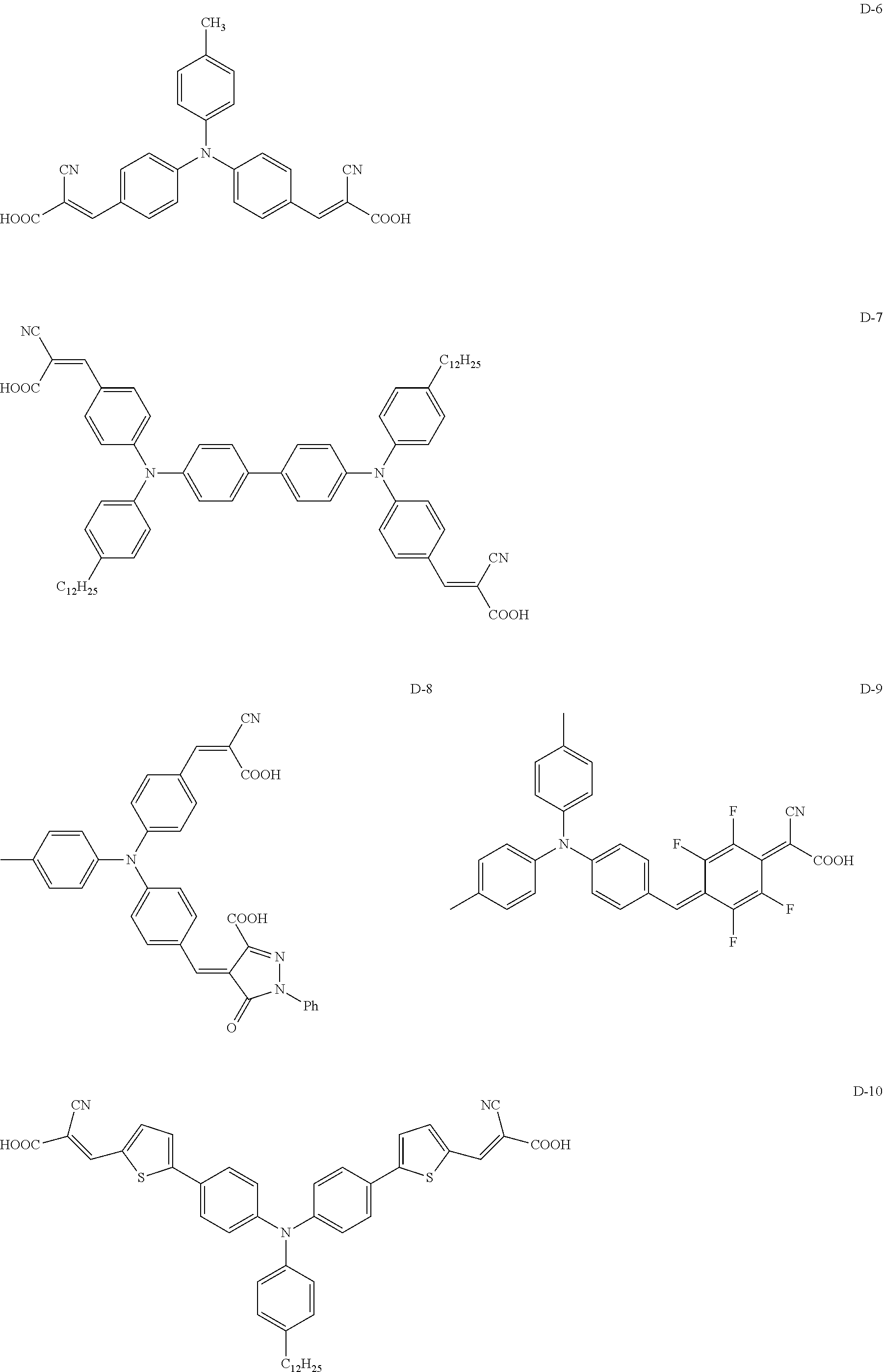

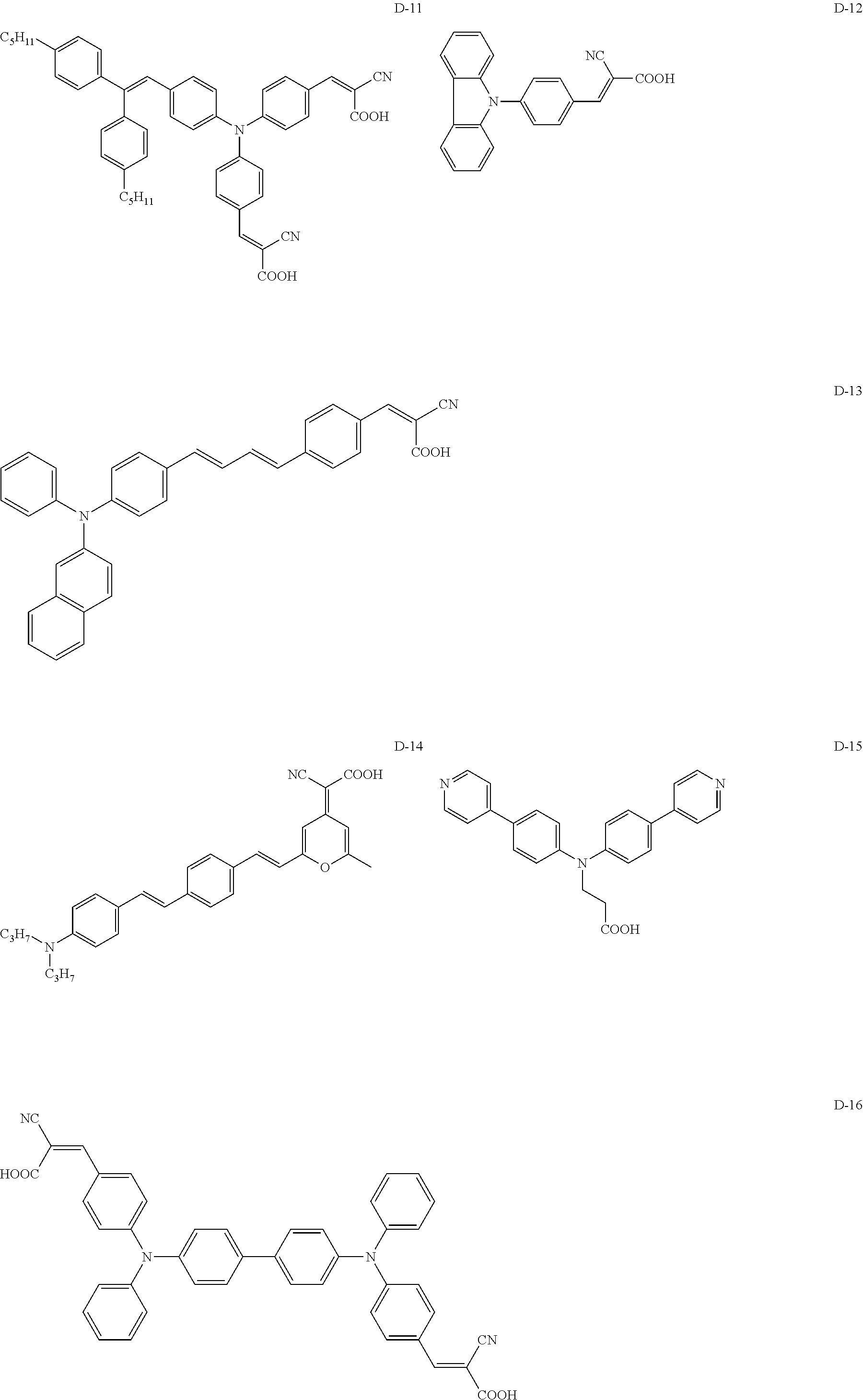

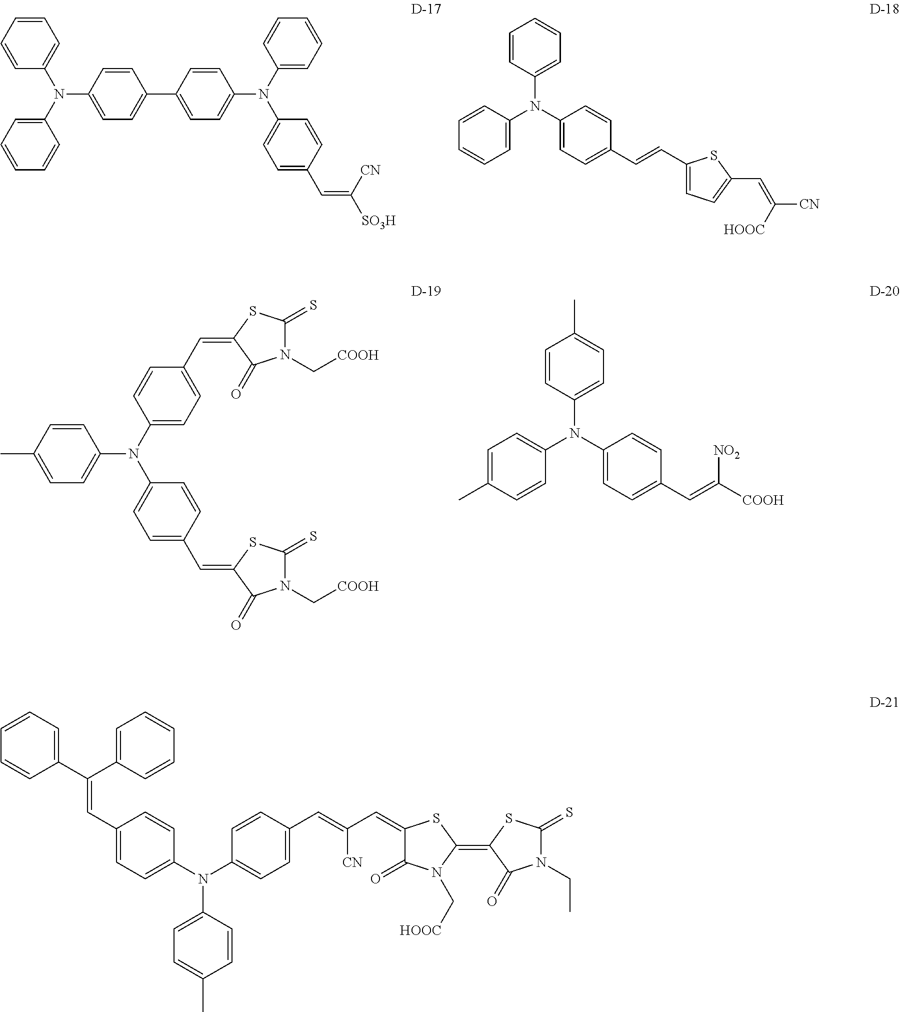

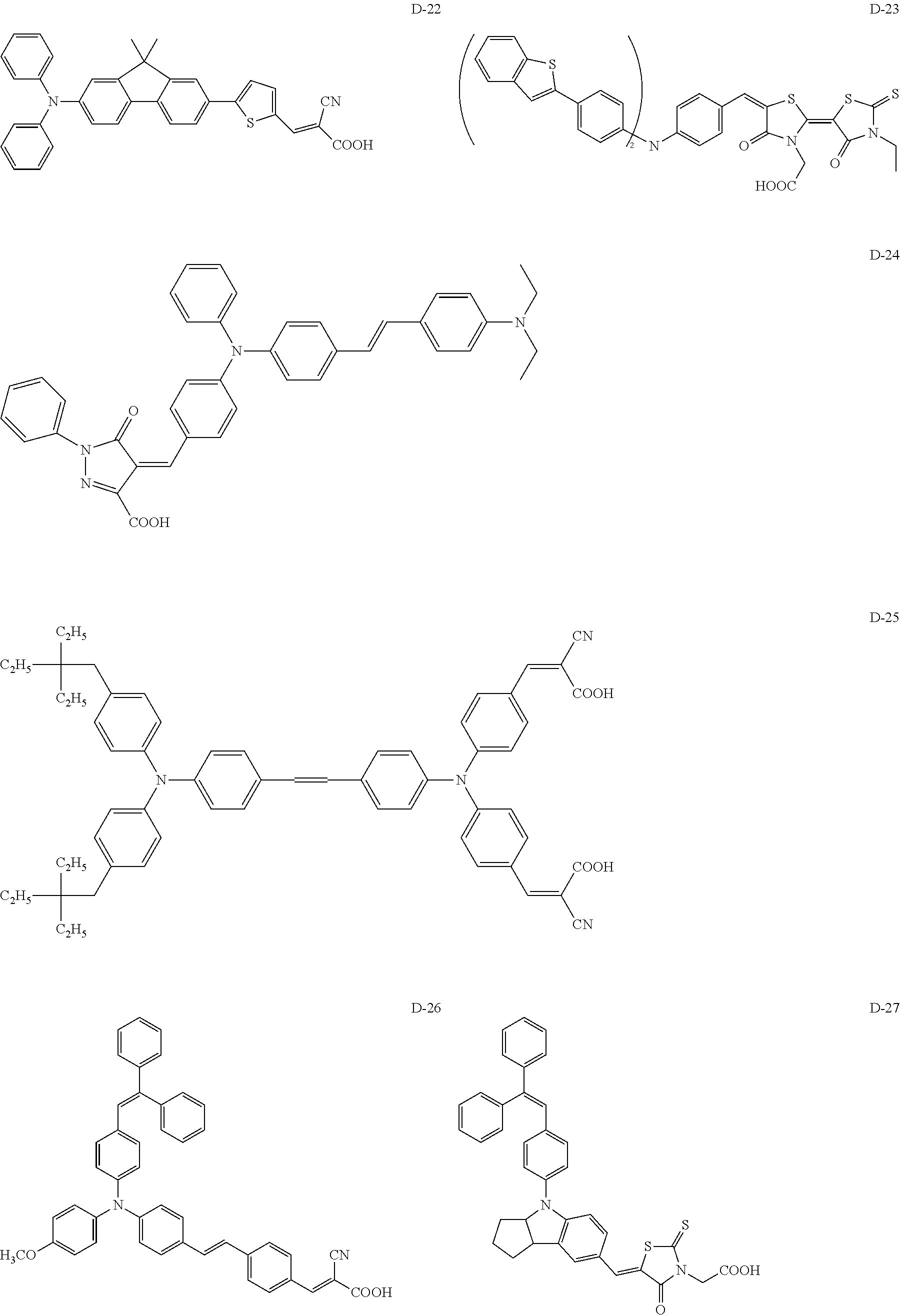

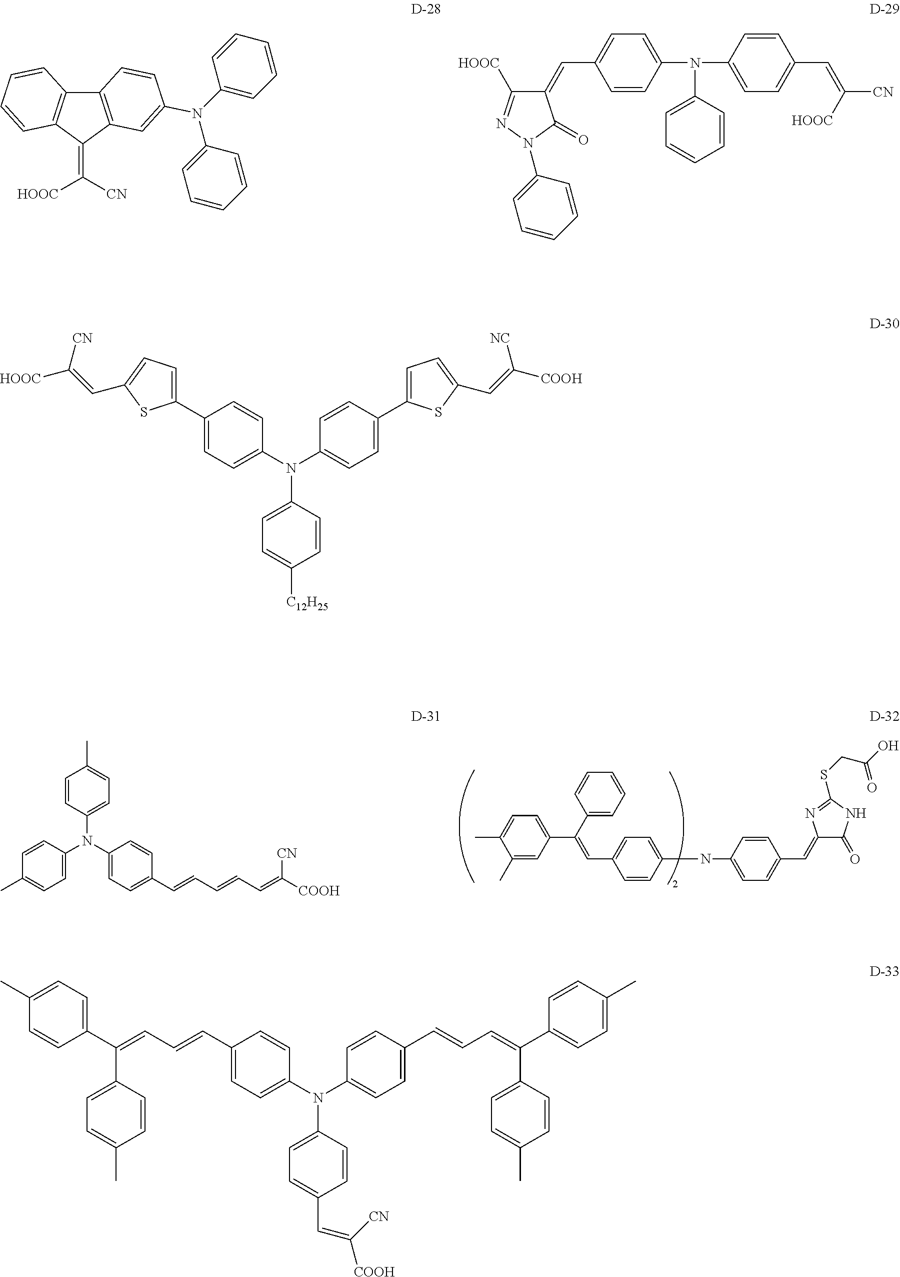

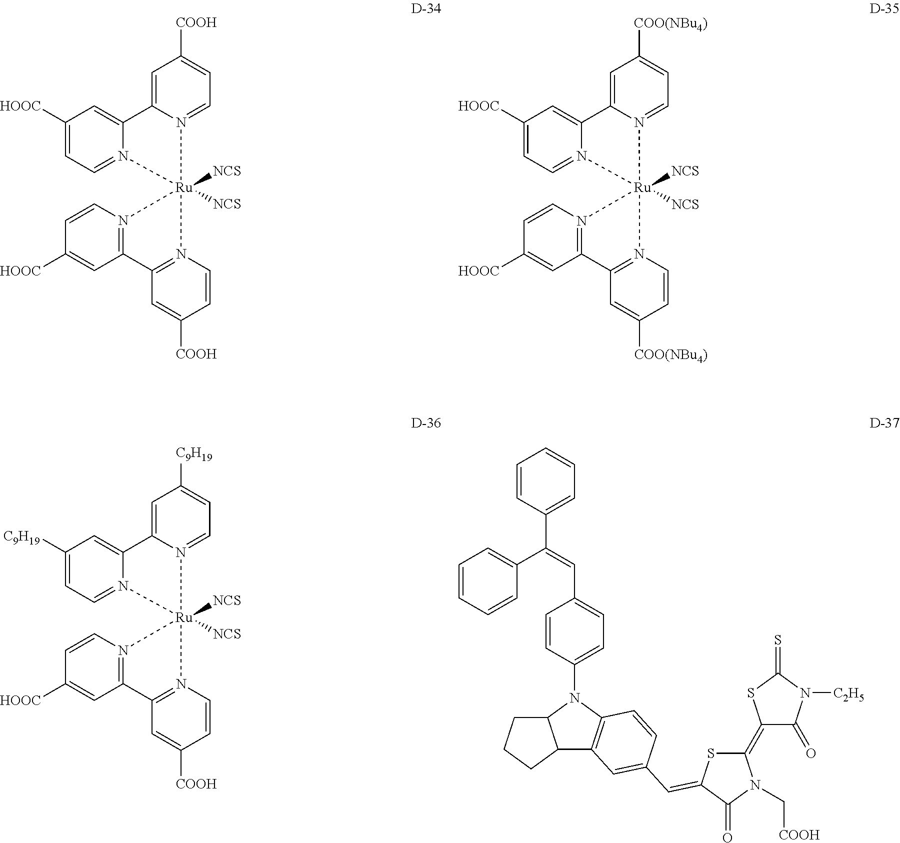

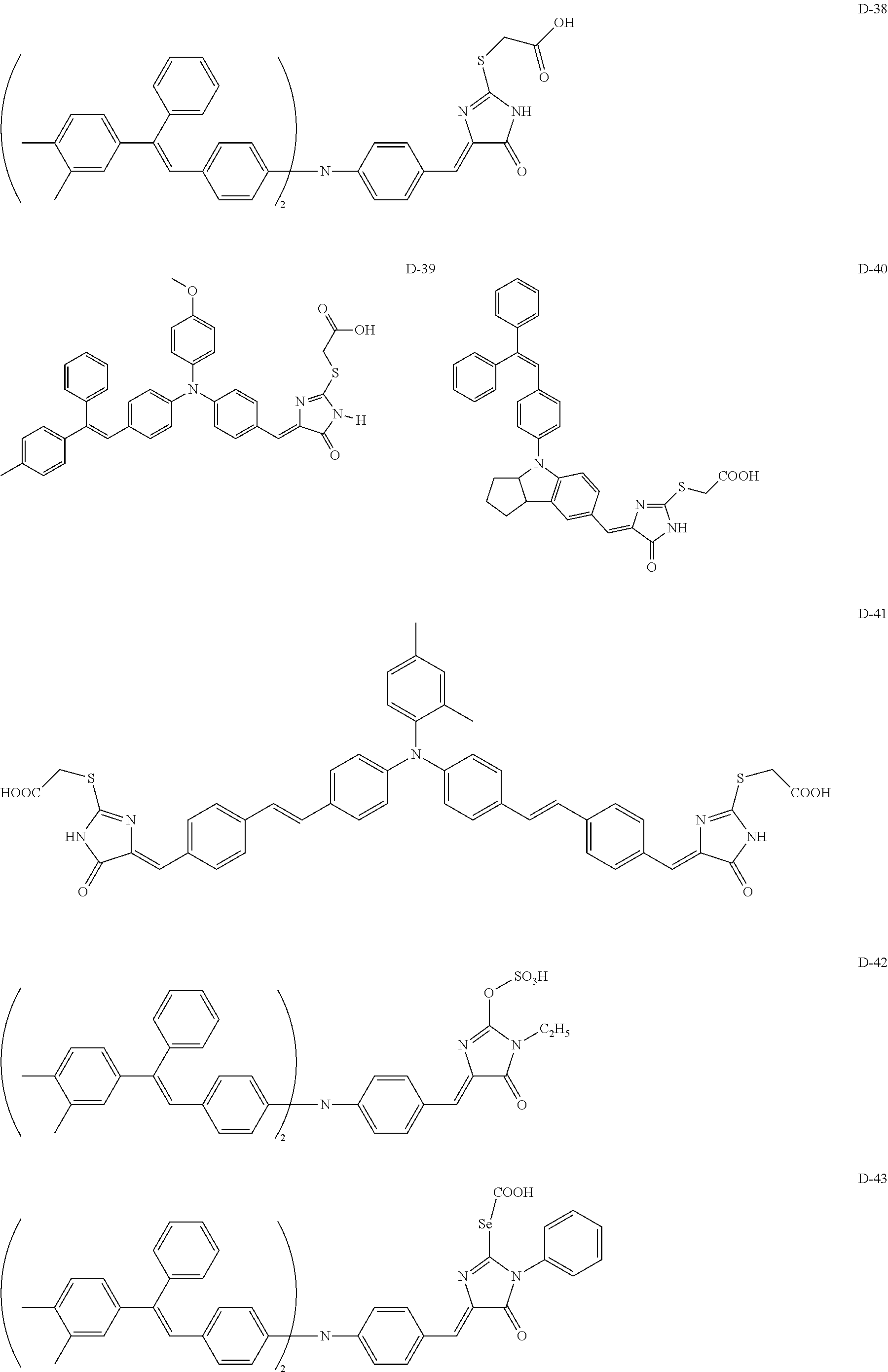

### [Co-Adsorption Compound]

The co-adsorption compound is a compound represented by Formula (1) described above. In Formula (1) described above, M represents a metal atom, and n is an integer of 2-5 and represents valence of metal. The metal atom is preferably divalent. The reason is as follows. Since a conduction electron level of a semiconductor material is positively shifted via adsorption of a metal atom portion in a co-adsorption compound onto the surface of a semiconductor material in cases where the metal atom is divalent or more, an effect through which a photoelectric conversion efficiency is improved is largely obtained when an injection ratio of electrons excited via light adsorption of a sensitizing dye into the semiconductor material is improved, but since solubility to a solvent becomes low in cases where the metal atom is trivalent or more, a large amount of time is consumed for the after-mentioned step of adsorbing a co-adsorption compound. Further, since generally, transition metals have absorption bands in the visible light region, and results in an obstructive factor to light absorption produced by a sensitizing dye, the metal atom is preferably an element in Group 2 or Group 12 as a main group element which easily becomes a divalent ion.

Further, in Formula (1) described above, R represents a monovalent organic group having a straight chain structure possessing no substituent, which has at least 6 atoms in chain length at the terminal, and specifically, preferably represents a straight chain alkyl group having 6-30 carbon atoms. When organic group R has a straight chain structure having no substituent, which has at least 6 atoms in chain length at the terminal, shape in which a projected area obtained by being projected from the molecule long axis direction is small, that is, an elongate shape is easy to be obtained. In this situation, a co-adsorption compound is easy to be adsorbed onto a non-adsorption site in each of various kinds of large and small shapes, which is present on the surface of a semiconductor material (clearance portions where no sensitizing dye adsorbed onto the semiconductor material is present). Accordingly, it is possible to make a coverage factor at the non-adsorption site caused by the co-adsorption compound to be large, and specifically, this effect can be surely obtained when organic group R is a straight chain alkyl group having 6-30 carbon atoms. When organic group R is a straight chain alkyl group having 6 carbon atoms or more, distance between the surface of a semiconductor material and charge transport layer 15 can be appropriately separated. When organic group R is a straight chain alkyl group exceeding 30 carbon atoms, a large amount of time is consumed for the after-mentioned step of adsorbing a co-adsorption compound since solubility to a solvent becomes low.

Specific examples of organic group R are represented by Formulae (R-1), (R-2), (R-3), (R-4), (R-5), (R-6), (R-7) and (R-8) as shown below, but the present invention is not limited thereto.

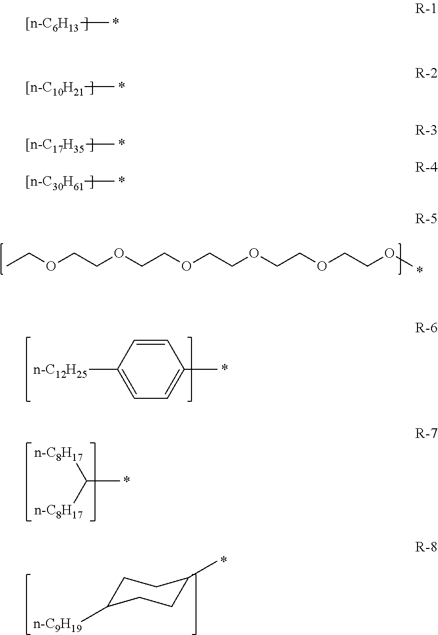

Further, in Formula (1) described above, A represents an oxo acid group, and in particular, preferably represents a carboxylic acid group in view of adsorption onto the surface of a semiconductor material.

Specific examples of group A are represented by Formulae (A-1), (A-2), (A-3), (A-4), (A-5), (A-6) and (A-7) as shown below, but the present invention is not limited thereto.

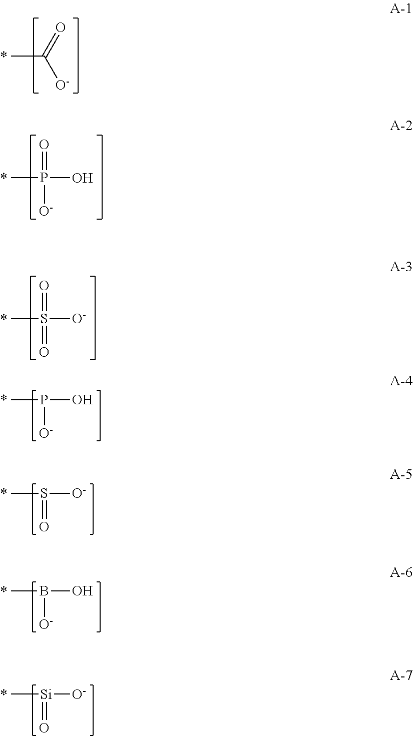

Specific examples of the co-adsorption compound are represented by Formulae (RAM-1), (RAM-2), (RAM-3), (RAM-4), (RAM-5), (RAM-6), (RAM-7) and (RAM-8) as shown below, but the present invention is not limited thereto. The following co-adsorption compounds can be used singly, or in mixture hi combination with at least two kinds thereof.

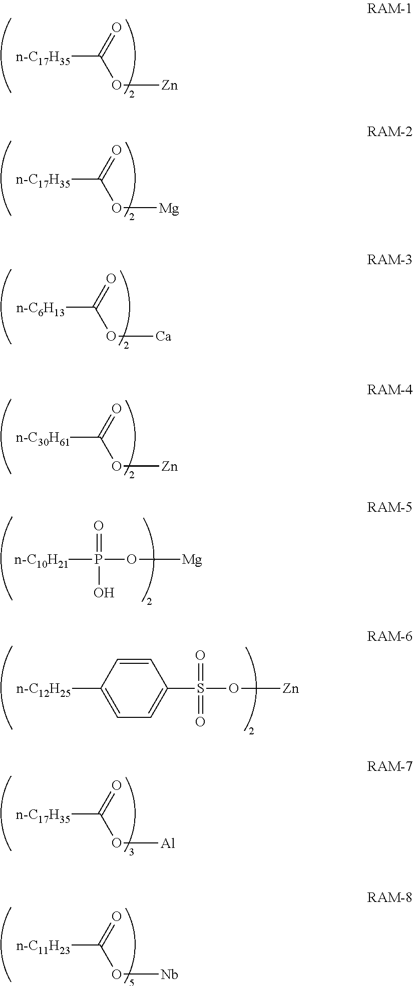

### [Method of Forming Photoelectric Conversion Layer]

After conducting a step of forming a semiconductor layer by which the semiconductor layer made of a semiconductor material is formed in order to form photoelectric conversion layer 14 on insulating layer 13 provided on first electrode layer 11b in conductive support 11, a step of adsorbing a sensitizing dye by which the sensitizing dye is adsorbed onto the surface of the semiconductor layer and a step of adsorbing a co-adsorption compound by which the co-adsorption compound is adsorbed onto the surface of the semiconductor layer are conducted to form photoelectric conversion layer 14 as described above. Specifically, in order to improve photoelectric conversion efficiency by expanding a coverage area covered by the sensitizing dye on the surface of a semiconductor layer, the step of adsorbing a co-adsorption compound is preferably carried out after conducting the step of adsorbing a sensitizing dye.

### [Step of Forming Semiconductor Layer]

The semiconductor layer can be formed via, for example, calcination. Specifically, in cases where a semiconductor relating to the present invention is particle-shaped, the semiconductor layer is formed by conducting a calcination treatment after coating or spraying the semiconductor onto insulating layer 13. Further, in cases where the semiconductor relating to the present invention is in the form of a film, the semiconductor layer is formed by conducting a calcination treatment after attaching the semiconductor onto insulating layer 13.

A step of forming a semiconductor layer in cases where the semiconductor of the present invention is particle-shaped will be described below. Semiconductor powder to form the semiconductor layer is first dispersed in a solvent to prepare a semiconductor powder-containing coating solution. The primary particle diameter of semiconductor powder to be used is preferable as fine as possible. For example, the semiconductor powder preferably has a primary particle diameter of 1-5000 nm, and more preferably has a primary particle diameter of 2-50 nm. The semiconductor powder dispersed in a solvent is dispersed in the form of the primary particle. The solvent is not specifically limited as long as it is one capable of dispersing the semiconductor powder. As the solvent, usable are water, an organic solvent, a mixture of water and an organic solvent, and so forth. As the organic solvent, for example, alcohol such as methanol, ethanol or the like, ketone such as methyl ethyl ketone, acetone, acetylacetone, or the like, and hydrocarbon such as hexane, cyclohexane or the like. A surfactant and a viscosity controlling agent (polyhydric alcohol such as polyethylene glycol or the like) can be added into a semiconductor powder-containing coating solution, if desired. The content of the semiconductor powder in the solvent is preferably 0.1-70% by weight, and more preferably 0.1-30% by weight.

Next, the semiconductor powder-containing coating solution is coated or sprayed onto insulating layer 13, subsequently followed by drying to form a film, and the resulting film is burned to form a semiconductor layer. The film before calcination is formed from a particle-shaped semiconductor aggregation, and the particle diameter of the particle corresponds to the primary particle diameter of utilized semiconductor powder. Such a film exhibits weak bonding force with insulating layer 13 and weak mutual bonding force between particles, and also exhibits weak mechanical strength, but the resulting semiconductor layer is mechanically strengthened via a calcination treatment, and is firmly attached onto insulating layer 13. The calcination treatment is conducted in air or inert gas. Temperature of the calcination treatment is designed to be a temperature lower than heat-resistance temperature of transparent substrate 11a constituting conductive support 11, and is set to a temperature of 50-300° C. and preferably a temperature of 100-250° C.

The thickness of a semiconductor layer after conducting a calcination treatment may be a thickness based on the desired thickness of photoelectric conversion layer 14.

### [Step of Adsorbing Sensitizing Dye]

It is performed to adsorb a sensitizing dye onto a semiconductor layer by immersing a structural material in which the above-described semiconductor layer is formed in immersion liquid in which a sensitizing dye is dissolved in an appropriate solvent. It is preferably performed to adsorb the sensitizing dye before moisture content is adsorbed onto the semiconductor layer after forming the semiconductor layer via calcination.

The solvent to dissolve a sensitizing dye is not specifically limited as long as it can dissolve the sensitizing dye, and it neither dissolve a semiconductor, nor react with the semiconductor, and specific examples thereof include an alcohol based solvent such as methanol, ethanol, n-propanol, t-butyl alcohol or the like; a ketone based solvent such as acetone, methyl ethyl ketone or the like; an ether based solvent such as diethyl ether, di-isopropyl ether, tetrahydrofuran, 1,4-dioxane or the like; a nitrile based solvent such as acetonitrile, propionitrile or the like; a halogenated hydrocarbon based solvent such as methylene chloride, 1,1,2-trichlroethane or the like, and so forth. These may be used by mixing them. Of these, ethanol, t-butyl alcohol and acetonitrile are specifically preferable. It is preferred that each of these solvents has been subjected to distillation and deaeration in advance.

Time of immersing a structural material in which a semiconductor is formed, in immersion liquid is preferably 1-48 hours at 25° C., and more preferably 3-24 hours at 25° C. in order to accelerate sufficient adsorption and so forth by deeply penetrating a sensitizing dye into a semiconductor layer, and to suppress that a decomposition product made in the immersion liquid via decomposition of the sensitizing dye prevents adsorption of the sensitizing dye.

Temperature of the immersion liquid to immerse the structural material in which the semiconductor layer has been formed may be a temperature as no boiling temperature, and heating can be appropriately carried out. Specifically, for example, a temperature of 10-100° C. is preferable, and a temperature of 25-80° C. is more preferable.

### [Step of Adsorbing Co-Adsorption Compound]

Adsorption of a co-adsorption compound onto a semiconductor layer is performed by immersing a structural material in which the above-described semiconductor layer is formed, in a solution in which the co-adsorption compound is appropriately dissolved in a solvent.

The solvent to dissolve the co-adsorption compound can be used without any specific limitation as long as it can dissolve the co-adsorption compound, and neither dissolves a semiconductor material nor reacts with the semiconductor material. Specifically, usable examples thereof include an alcohol based solvent such as methanol, ethanol, n-propanol, t-butyl alcohol or the like; a ketone based solvent such as acetone, methyl ethyl ketone or the like; an ether based solvent such as diethyl ether, di-isopropyl ether, tetrahydrofuran, 1,4-dioxane or the like; a nitrile based solvent such as acetonitrile, propionitrile or the like; a halogenated hydrocarbon based solvent such as methylene chloride, 1,1,2-trichlroethane or the like, and so forth, and a mixed solvent thereof is also usable. Of these, specifically, ethanol, t-butyl alcohol and acetonitrile are preferably usable. As to a solvent to dissolve a co-adsorption compound, in order to suppress that adsorption of the co-adsorption compound onto the semiconductor layer is prevented via penetration of water content dissolved in the solvent, and gas into a semiconductor layer, the solvent is preferably subjected to deaeration and distillation in advance.

Time of immersing a co-adsorption compound in a dissolved solution is preferably 1-48 hours at 25° C., and more preferably 3-24 hours at 25° C. depending on temperature of the dissolved solution in order to accelerate sufficient adsorption and so forth by deeply penetrating the adsorption compound into a semiconductor layer, and to suppress that a decomposition product produced via decomposition of the co-adsorption compound prevents adsorption of the sensitizing dye. These temperature and time are preferable in cases where the semiconductor layer is specifically composed of a porous structure film.

The temperature of the dissolved solution during immersion may be a temperature at which the co-adsorption compound is not decomposed, and for example, it is preferably 10-100° C., and more preferably 25-80° C.

### [Charge Transport Layer]

Charge transport layer 15 constituting photoelectric conversion element 10 of the present invention serves as a layer to transport holes having been injected at the interface with a sensitizing dye into second electrode 16 by rapidly reducing an oxidant of the sensitizing dye. This charge transport layer 15 is composed of, specifically, a p-type semiconductor as a main component exhibiting hole transporting ability, and may be in the form of liquid or solid, but in cases where it is formed from an electrolyte solution, there appears a problem such as volatilization of a solvent, liquid leakage and dissolution withdrawal of the sensitizing dye. Therefore, one in the form of solid is specifically preferable.

The p-type semiconductor should have an ionization potential smaller than that of a sensitizing dye in photoelectric conversion layer 14. The p-type semiconductor has a different ionization potential, depending on kinds of the sensitizing dye used in photoelectric conversion layer 14, but for example, an ionization potential of 4.5-5.5 eV is preferable, and an ionization potential of 4.7-5.3 eV is more preferable.

Specific examples of the p-type semiconductor include a triarylamine derivative; aromatic hydrocarbon in which at least four rings are condensed, such as tetracene or the like; a polythiophene derivative, a polypyrrol derivative, a polyaniline derivative, a polyphenylene derivative, copper (I) chloride, copper (I) cyanide and so forth, but the present invention is not limited thereto. These can be used singly, or in mixture in combination with at least two kinds thereof.

The mean thickness of charge transport layer 15, that is, the mean distance separated between semiconductor electrode 12 and second electrode layer 16 is, for example, preferably 0.1-100 μm; more preferably 0.5-50 μm; and still more preferably 1-20 μm. When the mean thickness of electron transport layer 15 falls within the above-described range, it can be surely prevented that an efficiency of transferring holes to semiconductor electrode 12 from charge transport layer 15 (transferring efficiency) is lowered.

### [Second Electrode Layer]

Second electrode layer 16 is a facing electrode; material constituting second electrode layer 16 may be one exhibiting conductivity; and examples thereof include any conductive material such as platinum, gold, silver, copper, graphite or the like. Second electrode layer 16 is preferably a thin metal film brought into close contact with charge transport layer 15, and preferably, in particular, a thin film made of gold as chemically stable metal, in which the difference in work function with respect to charge transport layer 15 is small.

### [Method of Preparing Photoelectric Conversion Element]

Insulating layer 13 is formed on conductive support 11; photoelectric conversion layer 14 is formed on this insulating layer 13; charge transport layer 15 is subsequently formed on this photoelectric conversion layer 14; and second electrode layer 16 is further formed on this charge transport layer 15 to obtain photoelectric conversion element 10. The above-described photoelectric conversion element 10 is possible to be prepared in any of various structures, depending on application, and any of various structures thereof is not specifically limited.

As to a dye-sensitized solar cell as described above, short-circuiting between photoelectric conversion layer 14 and charge transfer layer 15 is inhibited, since a specific compound is contained in photoelectric conversion layer 14. Thus, a desired photoelectric conversion efficiency is obtained.

As described above, embodiments of the present invention have been specifically explained, but the embodiments of the present invention are not limited to the above-described examples, and various changes can be added therein.

### EXAMPLE

Next., embodiments of the present invention are specifically described, but the present invention is not limited thereto.

### Example 1

### Preparation Example of Dye-Sensitized Solar Cell SC-1 (Present Invention)

A dense titanium oxide thin film having a thickness of 30-50 nm was formed on a transparent conductive film (FTO) by dropping a solution in which 1.2 mL of tetrakisisopropoxy titanium and 0.8 mL of acetylacetone were diluted with 18 mL of ethanol onto a fluorine-doped tin oxide (FTO) conductive glass substrate (conductive support) having a sheet resistance of 20 Ω/□ to conduct film formation employing a spin coating method, followed by heating at 450° C. for 8 minutes. A titanium oxide paste {an anatase type, a primary average particle diameter of 18 nm (mean value obtained via microscopic observation), and ethyl cellulose dispersion} was coated on the above-described titanium oxide dense thin film by a screen printing method (a coating area of 25 mm²), followed by calcination at 200° C. for 10 minutes and at 500° C. for 15 minutes to form a titanium oxide thin film having a thickness of 4 μm. The resulting was immersed in a sensitizing dye solution in which a sensitizing dye represented by the above-described formula D-1 was dissolved in a mixed solvent of acetonitrile:t-butyl alcohol=1:1 so as to give a concentration of 5×10⁻⁴ mol/L, at room temperature for 3 hours to conduct a treatment of adsorbing the sensitizing dye. Then, the resulting was immersed in a chlorobenzene solution containing the above-described formula (zinc stearate) as a co-adsorption compound at a ratio of 0.5 mol/L at 70° C. for 60 minutes to conduct an adsorption treatment for a co-adsorption compound, followed by drying after washing with chlorobenzene, whereby a photoelectric conversion layer was formed. Thus, a semiconductor electrode was obtained.

This semiconductor electrode was immersed in an acetonitrile solution (an electropolymerization solution) containing bis-EDOT represented by the following Formula (B) at a ratio of 1×10⁻³ (mol/L), and Li[(CF₃SO₂)₂N] at a ratio of 0.1 (mol/L). A charge transport layer was formed on the surface of the semiconductor electrode by maintaining a holding voltage at −0.16 V for 15 minutes during exposure to light (a Xenon lamp at a light intensity of 22 mW/cm² was used, and a wavelength of 430 nm or less was cut off) coming from the direction of a photoelectric conversion layer, employing a semiconductor electrode as a working electrode, a platinum wire as a counter electrode, and Ag/Ag+ (AgNO₃ 0.01M) as a reference electrode. The resulting semiconductor/charge transport layer was washed with acetonitrile, followed by drying. In addition, the resulting charge transport layer had become an insoluble polymerization in a solvent.

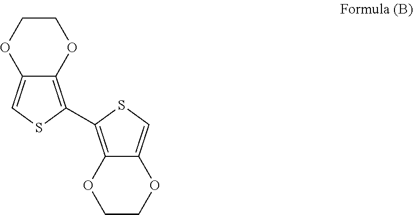

Thereafter, the semiconductor/charge transport layer was immersed in an acetonitrile solution containing Li[(CF₃SO₂)₂N] at a ratio of 15×10⁻³ (mol/L), and tert-butyl pyridine at a ratio of 50×10⁻³ (mol/L) for 30 minutes, followed by naturally drying, and subsequently, gold was further evaporated thereon by a vacuum evaporation method to prepare the second electrode. Thus, dye-sensitized solar cell [SC-1] was obtained.

### Example 2

### Preparation Examples of Dye-Sensitized Solar Cell SC-2 to SC-8 (Present Invention)

Each of dye-sensitized solar cells [SC-2]-[SC-8] was prepared similarly to preparation example of dye-sensitized solar cell SC-1, except that each of co-adsorption compounds shown in Table 1 was used as a co-adsorption compound.

### Comparative Example 1

### Preparation Example of Dye-Sensitized Solar Cell SC-R1 (Comparative Example)

Dye-sensitized solar cell [SC-R1] was prepared similarly to preparation example of dye-sensitized solar cell SC-1, except that a co-adsorption compound was not contained without conducting a step of containing the co-adsorption compound.

### Comparative Examples 2 and 3

### Preparation Example of Dye-Sensitized Solar Cell SC-R2, and Preparation Example of Dye-Sensitized Solar Cell SC-R3 (Comparative Examples)

Each of dye-sensitized solar cells [SC-R2] and [SC-R3] was prepared similarly to preparation example of dye-sensitized solar cell SC-1, except that each of magnesium acetate and lithium stearate was used in place of a co-adsorption compound.

### [Evaluation of Photoelectric Conversion Efficiency] (Initial Stage)

Current-voltage characteristics were measured at room temperature employing an 1-V tester while exposing each of the resulting dye-sensitized solar cells [SC-1]-[SC-8] and [SC-R1]-[SC-R3] as described above to pseudo solar light of 100 mW/cm² from a Xenon lamp, passing through an AM filter (AM 1.5) by using a solar simulator (manufactured by EKO INSTRUMENTS Co., Ltd.) to obtain each value of short-circuit current density (J_{SC}), open-circuit voltage (V_{OC}) and fill factor (F. F.). Photoelectric conversion efficiency η (%) was calculated from the following Expression (1) by using the foregoing values. The results are shown in Table 1.

Photoelectric conversion efficiency η (%)=[{V_{OC}(V)×J_{SC}(mA/cm²)×F. F.}/incident light intensity (mW/cm²)]×100 Expression (1)

TABLE 1

| | | | Dye-sensitized solar cell | | | Evaluation result |
|---|---|---|---|---|---|---|
| | | | Short-circuit | Open-circuit | | Photoelectric |
| | | Co-adsorption | current density | voltage | Fill | conversion |
| | No. | compound | (mA/cm²) | (mV) | factor | efficiency (%) |
| Example 1 | SC-1 | RAM-1 | 4.62 | 849 | 0.57 | 2.22 |
| Example 2 | SC-2 | RAM-2 | 4.96 | 856 | 0.60 | 2.55 |
| Example 3 | SC-3 | RAM-3 | 5.13 | 820 | 0.56 | 2.36 |
| Example 4 | SC-4 | RAM-4 | 4.56 | 889 | 0.60 | 2.43 |
| Example 5 | SC-5 | RAM-5 | 4.24 | 873 | 0.55 | 2.04 |
| Example 6 | SC-6 | RAM-6 | 4.48 | 825 | 0.57 | 2.11 |
| Example 7 | SC-7 | RAM-7 | 4.61 | 832 | 0.52 | 1.99 |
| Example 8 | SC-8 | RAM-8 | 4.89 | 798 | 0.53 | 2.06 |
| Comparative | SC-R1 | — | 3.06 | 839 | 0.59 | 1.51 |
| example 1 | | | | | | |
| Comparative | SC-R2 | (Magnesium | 3.61 | 754 | 0.58 | 1.59 |
| example 2 | | acetate) | | | | |
| Comparative | SC-R3 | (Lithium | 4.08 | 761 | 0.59 | 1.85 |
| example 3 | | stearate) | | | | |

As is clear from Table 1, it was confirmed that dye-sensitized solar cells [SC-1]-[SC-8] each containing a co-adsorption compound of the present invention had higher short-circuit current density and photoelectric conversion efficiency than those of dye-sensitized solar cell [SC-R2] in which a compound possessing no monovalent organic group having a straight-chain structure having no substituent but at least 6 atoms in chain-length at a terminal was used as a co-adsorption compound, and those of dye-sensitized solar cell [SC-R3] in which a compound made from metal atoms each having a valence of 1 was used as a co-adsorption compound. It was specifically confirmed that dye-sensitized solar cells [SC-1]-[SC-4] each in which metal atom M was a divalent element in Group 2 or Group 12; organic group R was a straight-chain alkyl group having 6-30 carbon atoms; and oxo acid group A was a carboxylic acid group produced excellent short-circuit current density and open-circuit voltage.

### EFFECT OF THE INVENTION

Desired photoelectric conversion efficiency can be obtained with a dye-sensitized solar cell of the present invention by suppressing short-circuiting between a photoelectric conversion layer and a charge transport layer since a specific compound is contained in the photoelectric conversion layer.

Further, a dye-sensitized solar cell exhibiting high photoelectric conversion efficiency can be surely obtained by a method of manufacturing the dye-sensitized solar cell of the present invention when short-circuiting between the photoelectric conversion layer and the charge transport layer is suppressed.

What is claimed is:

1. A dye-sensitized solar cell comprising a photoelectric conversion element comprising a substrate and layered thereon, a first electrode layer, a photoelectric conversion layer in which a sensitizing dye is carried onto a semiconductor material, a charge transport layer and a second electrode layer in this order,
wherein the photoelectric conversion layer comprises a compound represented by the following Formula (1):
(R-A)ₙ-M Formula (1)
where R represents a monovalent organic group having a straight-chain structure having no substituent but at least 6 atoms in chain-length at a terminal, A represents an oxo acid group, M represents a metal atom, and n is an integer of 2-5.

2. The dye-sensitized solar cell of claim 1,
wherein n in Formula (1) is 2, and M represents an element in Group 2 or Group 12.

3. The dye-sensitized solar cell of claim 1,
wherein R in Formula (1) represents a straight-chain alkyl group having 6-30 carbon atoms.

4. The dye-sensitized solar cell of claim 1,
wherein A in Formula (1) represents a carboxylic acid group.

5. The dye-sensitized solar cell of claim 1,
wherein the charge transport layer is in the form of a solid.

6. The dye-sensitized solar cell of claim 1,
wherein the semiconductor material comprises titanium oxide.
